(19) United States
(12) Patent Application Publication
(10) Pub. No.: US 2006/0003101 A1
(43) Pub. Date: Jan. 5, 2006

(54) Method of pre-cleaning wafer for gate oxide formation

(75) Inventors: Teresa Yim, Bukjeju-gun (KR); Byoung Yoon Seo, Yeoju-gun (KR); Yong Su Hoh, Daegu-si (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/172,204

(22) Filed: Jun. 29, 2005

(30) Foreign Application Priority Data
Jun. 30, 2004 (KR) 10-2004-50058

(51) Int. Cl. C23C 16/00; C03C 23/00; B08B 3/00

(52) U.S. Cl. 427/248.1; 134/26; 134/2

(57) ABSTRACT

A method of pre-cleaning a wafer for gate oxide formation is described. In the method, a wafer is loaded into a cleaning bath, and a cleaning agent such as diluted HF is supplied into the bath so as to remove contaminants from the back surface of the wafer. Then the cleaning agent is drained from the bath, and the wafer is rinsed with DI water. During this DI rinsing step, contaminants removed from the wafer may remain as impurities and bind to or combine with silicon on the front surface of the wafer. To remove such impurities from the wafer, a second cleaning agent is supplied again into the bath. After removal, the second cleaning agent is drained from the bath, and the wafer is rinsed again with DI water. Finally, and optionally, the wafer may be treated with HCl and ozone.

### CROSS REFERENCE TO RELATED APPLICATIONS

This U.S. non-provisional application claims priority under 35 U.S.C. §119 from Korean Patent Application No. 2004-50058, which was filed in the Korean Intellectual Property Office on Jun. 30, 2004, the contents of which are incorporated by reference herein in its entirety.

### BACKGROUND OF THE INVENTION

1. Field of the Invention

The present invention relates generally to wafer cleaning technology and, more particularly, to a method of pre-cleaning a wafer before gate oxide is formed.

2. Description of the Related Art

In the last several decades, semiconductor device technologies have been improving at a dramatic rate along with an amazing increase in the complexity of integrated circuits and a remarkable growth of related process techniques. Some improvements in transistors are due to reductions in channel length and gate oxide thickness, which result in higher speed. Wet cleaning, a frequently repeated step in wafer fabrication, is one of the most critical steps in forming a thin gate oxide.

The main purpose of the cleaning process is to reduce a variety of contaminants to a minimum before and/or after certain steps of wafer fabrication. In general, contaminants on the wafer surface may include particles, organics, metals, and native oxides. Especially, particles may cause unwanted defects in equipment and/or on wafers and a drop in yield. In addition, metallic contaminants may lead to a degradation in gate oxide integrity, an increase in leakage current, a reduction in retention time, and so forth. In order to remove such contaminants, cleaning solutions (or mixtures thereof) for each contaminant have been used in the wet cleaning process. The ideal aim of the cleaning process is to remove all of the contaminants from the wafer surface. This may, however, be very difficult to accomplish in fact.

One conventional cleaning method has been disclosed in the Korean Patent Publication No. 2000-2904. According to this disclosure, a cleaning method includes a washing step using an oxidizer such as H₂O₂ after a chemical treating step using a fluoride such as HF. This cleaning method may, however, have the following drawbacks.

The chemical treatment removes contaminants from the back surface of the wafer and thus produces impurities (that is, reaction products of contaminant removal). As the chemical treatment advances, the concentration of the impurities in the cleaning solution becomes higher. Furthermore, the concentration of active cleaning agent(s) (e.g., reacting substance[s] in the cleaning solution) decreases, thereby reducing the reaction rate. During a subsequent DI rinse step, the impurities remaining in the cleaning solution may combine with reactive species (e.g., silicon dangling bonds) on the front surface of the wafer. Such chemically combined impurities may not be completely removed by HCl.

In a cleaning bath, the impurities may be concentrated in an upper part of the bath than at a lower part because DI water is generally supplied from the lower part of the bath (e.g., from underneath the wafers). The chemically combined impurities may be therefore produced chiefly in an upper region of the wafer. During a subsequent ozone treatment, an oxide film grows by combining oxygen-containing species (e.g., oxygen atoms) with silicon (e.g., on the surface, having dangling bonds) that has not combined with impurities. Thus no oxide is formed in locations where the chemically combined impurities exist, and therefore, this may cause a non-uniform oxide film. Unfortunately, a defective, non-uniform oxide may result in defects on the wafer, especially on the upper region of the wafer.

### SUMMARY OF THE INVENTION

The inventors recognized the above-discussed mechanism of impurity transformation in a gate oxide pre-cleaning process and now provide the present invention to increase the yield in the gate oxide pre-cleaning method.

According to one exemplary embodiment of the present invention, a method of pre-cleaning a wafer for gate oxide formation comprises a first step of removing contaminants from a back surface of a wafer (e.g., by wet etching), and a second step of removing chemically combined impurities from a front surface of the wafer (e.g., by wet etching).

According to another exemplary embodiment of the present invention, a method of pre-cleaning a wafer for gate oxide formation includes loading one or more wafers into a bath, supplying a first diluted HF into the bath so as to remove contaminants from a back surface of the wafer(s), draining the first diluted HF from the bath, and rinsing the wafer(s) with first DI water. The pre-cleaning method further includes supplying a second diluted HF into the bath so as to remove impurities (which may be chemically combined with species on the wafer) from a front surface of the wafer(s), draining the second diluted HF from the bath, and rinsing the wafer(s) with second DI water. In a further embodiment, the method relates to forming a gate oxide film, and further includes treating the wafer with HCl and ozone.

### BRIEF DESCRIPTION OF THE DRAWINGS

FIG. 1 shows a front-to-back loading format of wafers used in a wafer cleaning method.

FIG. 2 shows a front-to-front loading format of wafers used in a wafer cleaning method.

FIG. 3 is a graph showing a yield distribution in a conventional method of pre-cleaning a wafer.

FIG. 4 shows a yield map in a conventional method of pre-cleaning a wafer.

FIG. 5 depicts a general mechanism of impurity transformation in a method of pre-cleaning a wafer.

FIG. 6 is a graph showing a yield distribution in a wafer cleaning method according to the present invention in comparison with a conventional method.

FIG. 7 shows a yield map of wafers cleaned according to the present invention, in comparison with a wafer cleaned according to a conventional method.

FIG. 8A is a graph showing results of the film thickness measurement (FTM) for a gate oxide after pre-cleaning according to the present invention in comparison with a conventional method.

FIG. 8B is a graph showing results of the breakdown failure measurement (BFM) for a gate oxide after pre-cleaning according to the present invention in comparison with a conventional method.

FIG. 8C is a graph showing results of the time dependent dielectric breakdown (TDDB) for a gate oxide after pre-cleaning according to the present invention in comparison with a conventional method.

### DETAILED DESCRIPTION OF EXEMPLARY EMBODIMENTS OF THE INVENTION

Exemplary, non-limiting embodiments of the present invention will now be described more fully hereinafter with reference to the accompanying drawings. This invention may, however, be embodied in many different forms and should not be construed as limited to the exemplary embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention. Thus, although preferred embodiments of the invention relate to pre-cleaning a wafer for subsequent formation of a gate oxide film (also sometimes called “gate oxide pre-cleaning”), the invention is also applicable to cleaning wafers (particularly with exposed silicon surfaces) prior to subsequent formation of a film (e.g., a silicon-containing film, such as a silicon oxide, nitride or oxynitride film or a metal silicide film, particularly a film formed from a chemical reaction with exposed silicon, such as a wet or dry thermally-grown silicon dioxide film or a metal silicide film).

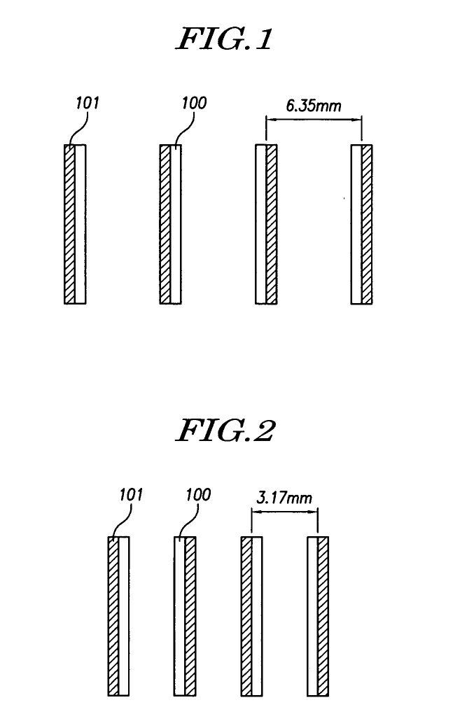

FIGS. 1 and 2 show respectively, in schematic views, a front-to-back loading format and a front-to-front loading format that are typically used in a wafer cleaning method. As shown in FIG. 1, the front-to-back loading format arranges two wafers of the group of wafers being precleaned (and generally, only two such wafers) so that their front surfaces 100 face each other. The other wafers in the group are arranged so that their front surfaces 100 may face back surfaces 101 of adjacent wafers. The front-to-front loading format, shown in FIG. 2, arranges all the wafers so that their front surfaces 100 face each other (i.e., the front surface of one wafer faces the front surface of an adjacent wafer, or pairs of wafers are arranged so that they face each other).

Precise thickness control of a gate oxide is very important to transistors on a chip. For example, in 0.13 μm process technology, a high-performance logic device generally contains a gate oxide having a thickness of 1.5˜1.9 nm, a low-power device generally contains a gate oxide having a thickness of 2.5˜2.9 nm, and a 2.5V I/O interface device generally contains a gate oxide having a thickness of about 5.0 nm. Such small oxide thicknesses are greatly influenced by the gate oxide pre-cleaning process.

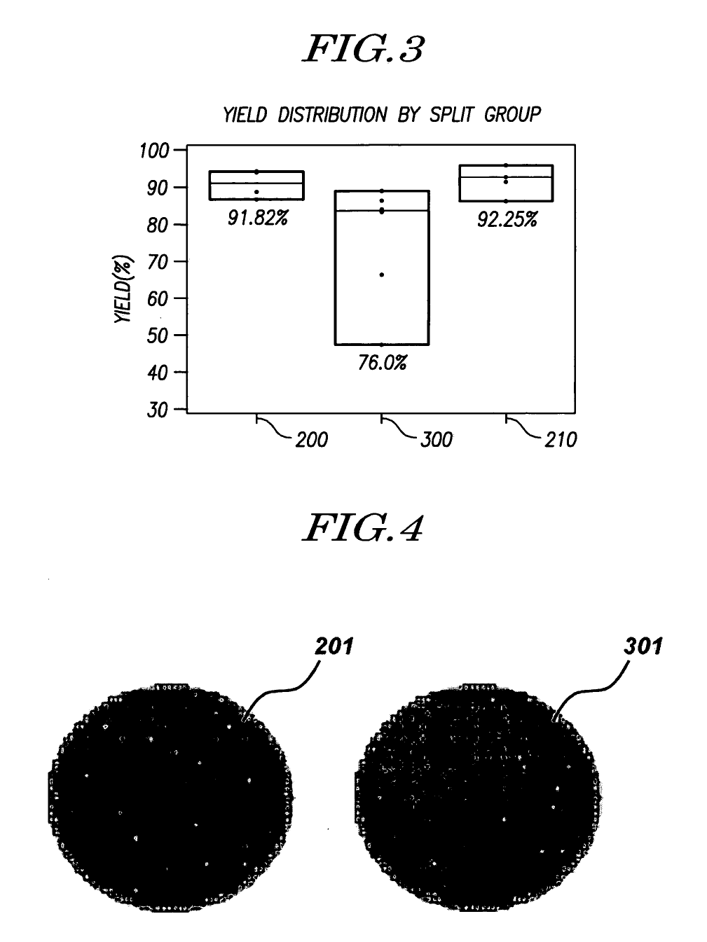

FIGS. 3 and 4 show respectively a yield distribution and a yield map in a conventional method of gate oxide pre-cleaning. As shown in FIG. 3, the yield is relatively higher in front-to-front loading formats 200 and 210 than in a front-to-back loading format 300. These results may demonstrate the effect of contaminants from a wafer backside that may react with or bond to front surfaces of a wafer (e.g., exposing silicon that may or may not have dangling bonds) during a gate oxide precleaning process. Similarly, the yield map shown in FIG. 4 is relatively clearer in a front-to-front loading format 201 than in a front-to-back loading format 301. Also, there is a relatively high concentration of defective die on the upper half of wafer 301, demonstrating the phenomenon described above with regard to contaminants concentrating in the upper portion of the cleaning bath.

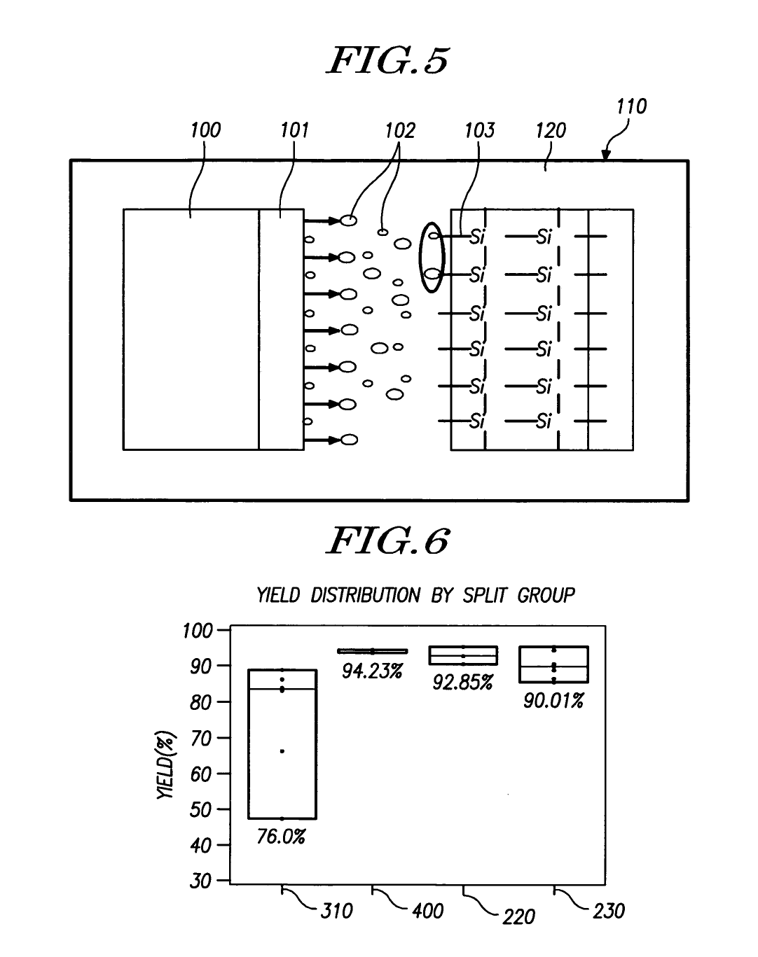

FIG. 5 shows a general mechanism of impurity transformation in a method of cleaning a wafer for subsequent gate oxide formation. Referring to FIG. 5, a pair of wafers are loaded in the front-to-back loading format into a cleaning bath 110. DI wafer 120 is supplied into the bath 110 from a lower part of the bath 110.

In general, impurities removed from surfaces of the wafer by a cleaning solution may be harmless products. However, in most cases, such impurities still remain in the cleaning solution, and as pre-cleaning progresses, the concentration of the impurities generally continuously increases. Increasing impurities may act as potential contaminants in the bath. On the other hand, as the impurity removal reaction on the wafer surfaces advances, the concentration of reacting substance(s) in the cleaning solution gradually decreases. Furthermore, such decreasing concentration of the reacting substance reduces the removal reaction rate.

FIG. 5 shows a DI rinse step performed after a cleaning step using diluted HF. Although cleaning with dilute HF is a preferred embodiment, the invention may use any conventional or generally-recognized agent or solution for cleaning wafers, particularly those having exposed silicon surfaces. The impurities 102 removed from the back surface 101 of a first wafer may combine with silicon (e.g., having dangling bonds 103) on the front surface 100 of another (e.g., the adjacent) wafer. Since DI wafer 120 is supplied from the lower part of the bath 110, the concentration of diluted HF and/or impurities decreases rapidly in the lower part of the bath in comparison with the upper part of the bath 110. So there is a strong possibility of creating chemically combined (or bound) impurities in an upper region of the wafer. These chemically combined impurities may not be completely removed by HCl.

During subsequent ozone treatment, an oxide film grows by combining oxygen-containing species (e.g., oxygen atoms) with silicon (e.g., silicon having dangling bonds) that has not combined or reacted with impurities. Thus, no oxide is formed at locations where the chemically combined impurities exist. Therefore, impurities bound to the silicon surface of a wafer may cause non-uniform oxide films and resultant defects on the wafer.

In order to solve the above-discussed problem, an exemplary embodiment of the present invention provides a pre-cleaning method wherein contaminants are removed from the back surface of the wafer in a first step (which may comprise [wet] etching), and chemically combined impurities are removed from the front surface of the wafer in a second step (which may also comprise [wet] etching).

According to another exemplary embodiment of the present invention, the wafer(s) are loaded into the cleaning bath 110, and a cleaning solution or agent (e.g., diluted HF) is supplied into the bath 110 so as to remove contaminants from the back surface 101 of the wafer. Then the diluted HF is drained from the bath 110, and the wafer(s) are rinsed with DI water. During this DI rinsing step, impurities 102 (e.g., contaminants removed from the back surface 101 of the wafer) may combine with exposed silicon (e.g., having dangling bonds 103) on the front surface 100 of another (e.g., the adjacent) wafer. To remove such bound or chemically combined impurities from the front surface 100, a second cleaning solution or agent (e.g., diluted HF) is supplied again into the bath 110. After removal, the diluted HF is drained from the bath 110, and the wafer is rinsed again with DI water. Finally, in the embodiment of the invention relating to formation of a gate oxide film, the wafer is treated with HCl and ozone to grow the gate oxide film on the exposed silicon surfaces. Alternatively, the treatment with HCl and ozone further etches the wafer and completes the pre-cleaning process.

The bath 110 may be limited to particular shapes and/or arrangements, but a single bath form is preferred. The bath 110 may have a volume between ten and twenty liters. Additionally, the number of wafers loaded into the bath 110 may be any integer number (i.e., one or more), but preferably, the number will be from about forty-five to about fifty-five, and more specifically, about fifty. The wafers may be loaded using (or arranged in) a front-to-front loading format or a front-to-back loading format.

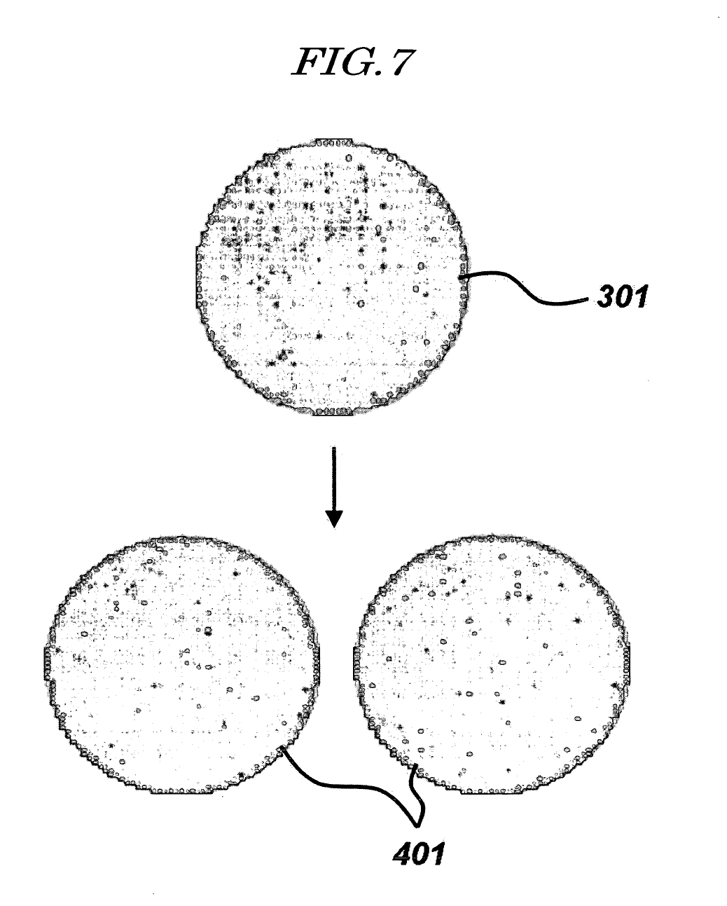

FIGS. 6 and 7 show respectively a yield distribution and a yield map for wafers pre-cleaned according to the present invention, in comparison with one or more wafers pre-cleaned according to a conventional method. FIG. 6 shows yield distributions for four groups of wafers. The first group 310 on the left indicates results after implementing a conventional pre-cleaning method using a front-to-back loading format. The third and fourth groups 220 and 230 indicate results after implementing a conventional pre-cleaning method using a front-to-front loading format. The second group 400 indicates results after implementing the method of the present invention using a front-to-front loading format. As shown in FIG. 6, the average yield according to the present invention is improved by 2-15%.

Additionally, referring to FIG. 7, a yield map 301 for a wafer pre-cleaned according to a conventional method includes several spots indicating defective die and/or a lower yield. Such defects tend to concentrate toward the upper region (e.g., the upper half) of the wafer. However, a yield map 401 for a wafer pre-cleaned according to the method of the present invention includes fewer spots, indicating less defects and a higher yield relative to the wafer pre-cleaned according to the conventional method.

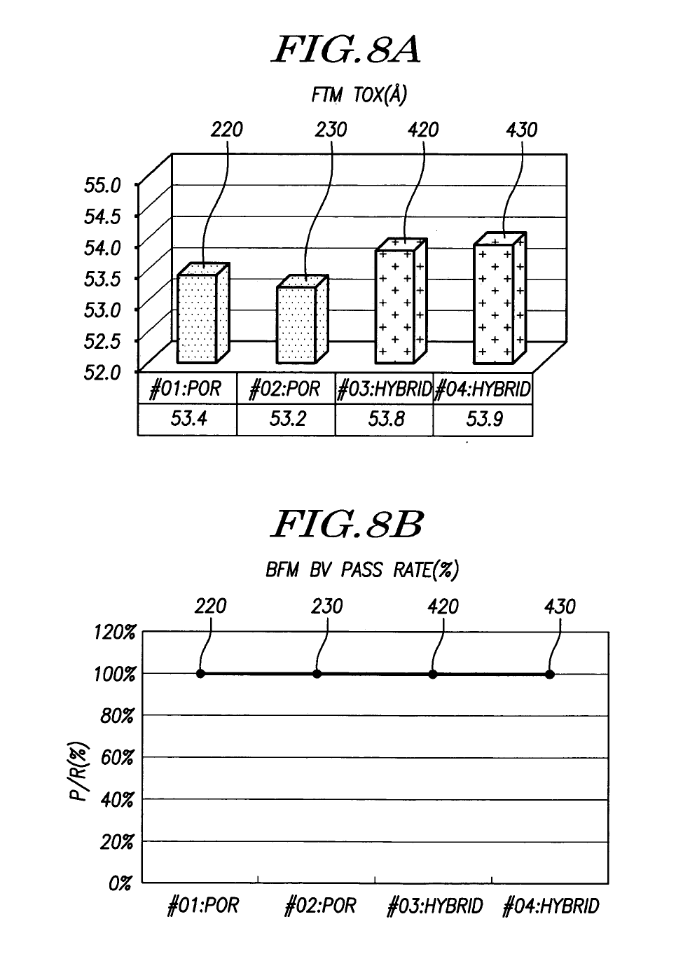

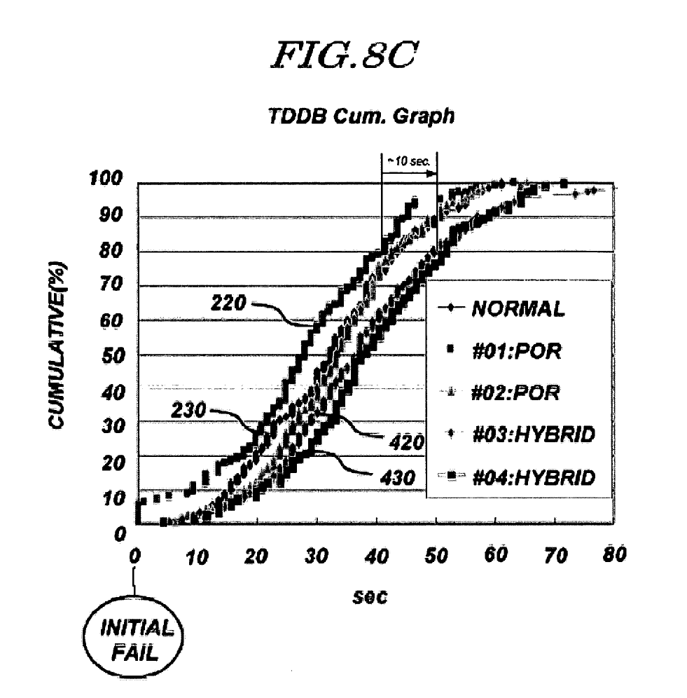

FIGS. 8A to 8C show, in graphs, results of measuring the gate oxide integrity (GOI) after pre-cleaning according to the present invention in comparison with a conventional method. Referring to FIG. 8A, the film thickness measurement (FTM) resulted in 53.2 Å and 53.4 Å in the cases of conventional methods 220 and 230, and 53.8 Å and 53.9 Å in the cases of the present invention methods 420 and 430. As shown by the results of the breakdown failure measurement (BFM) shown in FIG. 8B, no significant differences in gate oxide breakdown were found. Referring to FIG. 8C, the time dependent dielectric breakdown (TDDB) graph illustrates the result that dielectric breakdown time increases by about ten seconds in the case of the present invention.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A cleaning method, comprising:
loading one or more wafers into a bath;
supplying a first cleaning solution into the bath to remove contaminants from a back surface of the wafer(s);
draining the first cleaning solution from the bath;
rinsing the wafer with first DI water;
supplying a second cleaning solution into the bath to remove impurities from a front surface of the wafer;
draining the second cleaning solution from the bath; and
rinsing the wafer with second DI water.

2. The method of claim 1, wherein the bath has a volume of from about ten to about twenty liters.

3. The method of claim 1, wherein the number of wafers is from about forty-five to about fifty-five.

4. The method of claim 1, wherein the wafers are arranged in a front-to-front loading format.

5. The method of claim 1, wherein the wafers are arranged in a front-to-back loading format.

6. The method of claim 1, wherein the first and/or second cleaning solutions comprise diluted HF.

7. The method of claim 1, wherein the wafer(s) have an exposed silicon surface.

8. The method of claim 7, further comprising forming a silicon-containing film by a chemical reaction with the exposed silicon.

9. The method of claim 8, wherein the silicon-containing film comprises a wet or dry thermally-grown silicon dioxide film or a metal silicide film.

10. The method of claim 1, wherein the impurities comprise chemically combined impurities.

11. The method of claim 1, further comprising forming a silicon-containing film on the wafer(s).

12. The method of claim 11, wherein the silicon-containing film comprises a silicon oxide, nitride or oxynitride film or a metal silicide film.

13. The method of claim 1, further comprising forming a gate oxide film on the wafer(s).

14. The method of claim 1, further comprising treating the wafer with HCl and ozone.

15. A method of forming a gate oxide film, comprising:
the method of claim 1, and
treating the wafer with HCl and ozone.

16. A cleaning apparatus configured to perform the method of claim 1.

17. The apparatus of claim 1, comprising a bath having a volume of from about ten to about twenty liters.

18. The apparatus of claim 1, configured to process from about forty-five to about fifty-five wafers simultaneously.

19. The method of claim 1, wherein the wafers are arranged in a front-to-front loading format.

20. The method of claim 1, wherein the wafers are arranged in a front-to-back loading format.
